(19) United States
(12) Patent Application Publication
(10) Pub. No.: US 2010/0002404 A1
(43) Pub. Date: Jan. 7, 2010

(54) DISPLAY DEVICE AND METHOD OF MANUFACTURING THE SAME

(75) Inventors: Akira FUJITA, Kanagawa (JP); Yuji Kondo, Kanagawa (JP)

Correspondence Address: YOUNG & THOMPSON, 209 Madison Street, Suite 500, Alexandria, VA, 22314, US

(73) Assignee: NEC LCD TECHNOLOGIES, LTD, Kanagawa (JP)

(21) Appl. No.: 12/491,453

(22) Filed: Jun. 25, 2009

(30) Foreign Application Priority Data
Jul. 4, 2008 (JP) 2008-175273

(51) Int. Cl. H05K 5/00; H05K 3/20

(52) U.S. Cl. 361/752; 29/831

(57) ABSTRACT

A display device includes a glass substrate having a display area and a peripheral area. A drive circuit component is mounted on the glass substrate by thermocompression bonding on the peripheral area, and a stress absorption region is provided within the glass substrate close to the circuit component so as to absorb stress produced by thermal deformation of the circuit component. A method of manufacturing the display device of the present invention includes a step of forming stress absorption region into the glass substrate so as to absorb the stress caused by thermocompression bonding of the the circuit component.

This application is based upon and claims the benefit of priority from Japanese patent application No. 2008-175273, filed on Jul. 4, 2008 and the disclosure of which is incorporated herein in its entirety by reference.

### TECHNICAL FIELD

The present invention relates to a display device and its manufacturing method, and more particularly to the display device and its manufacturing method having a glass substrate on which a drive circuit component is mounted by using a thermocompression bonding.

### BACKGROUND ART

As an example of display devices, a liquid crystal display (LCD) device is widely used in industrial applications, and in recent years, a new market has been growing as display monitors in broadcasting stations and medical imaging devices. When using it at the place with very dark operating environment like the above-mentioned display monitors in the broadcasting stations, a slight brightness difference in a display screen is visually recognized remarkably compared with a case of a usual operating environment.

In particular, in an LCD device resorting to a COG (Chip On Glass) mounting, a large shrinkage stress occurs at an integrated circuit chip (hereinafter, referred to as an IC chip) which is a surface mounted component on a glass substrate for driving the LCD device. Because of this, the glass substrate is tended to be distorted greatly, and thus a display unevenness caused by deformation of the glass substrate occurs remarkably compared with the other installation methods. Particularly, the display unevenness greatly affects a display image when the image is darkly displayed. Accordingly, it is required to improve the display unevenness caused by the deformation of such glass substrate. For example, related technologies for improving the display unevenness are disclosed in Japanese Patent Application Laid-Open No. 2003-140564 (patent document 1) and Japanese Patent Application Laid-Open No. 2008-020836 (patent document 2) corresponding to US Patent Application Publication No. US 2008/0013030 A1.

As an example of mounting technologies of the drive circuit component for the display devices, in the LCD device for example, there are a so-called TCP (Tape Carrier Package) mounting method and a COF (Chip On Film) mounting method wherein a film package mounted with the IC chip as a drive circuit component on a flexible substrate is bonded on the glass substrate via an anisotropic conductive film (hereinafter, referred to as ACF) by using a thermocompression. However, concerning with increased demand for cost cutting and minute connection, the COG mounting method is a current mainstream which mounts the IC chip itself on the substrate directly.

The IC chip packaging method of a display panel for the LCD device by the conventional COG mounting method and the mounted structure will be described by referring to FIG. 12 through FIG. 15.

As shown in FIG. 12, a couple of glass substrates is bonded together such that a fixed gap is held between them to interpose a liquid crystal layer. On one glass substrate, although not illustrated, thin film transistors (TFTs), signal lines, scanning lines and pixel electrodes are arranged so as to form a TFT substrate 2. The signal lines and the scanning lines are extended from a display area 123 to a terminal electrode group (not shown) which is connected to each of IC chips 4 as a drive circuit components on a peripheral area 126. On the other glass substrate as a CF (Color Filter) substrate 3, common electrodes and color layers are formed (not illustrated).

In the COG mounting method, as shown in FIG. 13, ACFs 5 are printed onto those terminal electrodes formed on the TFT substrate 2 to be mounted with the IC chips 4. After that, the IC chips 4 are arranged on the ACFs 5 at right position. Next, the IC chip mounting areas are arranged on a compression bonding stage 7, and each of the ACFs 5 is hardened by arranging each of the IC chips 4 between the compression bonding tool 8 and the compression bonding stage 7 for a predetermined time with predetermined temperature and pressure.

Owing to these heating and pressurization, as shown in FIG. 14, the electrical connection is accomplished by pressing conductive particles 9 of the ACF 5 between projected electrodes 11 of the IC chip 4 and a group of terminal electrodes 10 of the TFT substrate 2. When the ACF resin is hardened, the IC chip 4 is fixed to the glass substrate (the TFT substrate 2) without losing the above-mentioned electrical connections.

However, in the above-mentioned IC chip mounting method, when the IC chip 4 is thermal-compressed, there a problem that the IC chip 4 warps in a concave shape due to thermal expansion difference between the IC chip 4 and the glass substrate (the TFT substrate 2).

The reason of such warping is as follows. Thermal expansion coefficient of the IC chip 4 is about 3 ppm which is approximately equal to that of the glass substrate which has the thermal expansion coefficient of about 3.8 ppm. However, the thermal capacity of the mounted IC chip 4 is sufficiently small compared with an entire glass substrate, and thus the IC chip 4 is thermally expanded owing to the heating by a compression bonding tool. In contrast, the thermal capacity of the glass substrate is sufficiently large compared with the IC chip 4 while almost no thermal expansion occurs to the IC chip mounting area because the thermal expansion deformation is restricted by the other glass substrate bonded to the TFT substrate 2. Since it is general that the ACF 5 is made of heat-curing type epoxy system resin, the ACF 5 is already hardened at heat declining process after the thermocompression bonding, and thus the IC chip 4 is fixed to the glass substrate. Accordingly, just after the thermocompression bonding, the IC chip 4 fixed on the glass substrate by the ACF 5 is in a state of thermally expanded, and thus as shown in FIG. 14, the IC chip 4 is transformed into the concave shape by the shrinkage stress due to the temperature decline.

The warping of this IC chip 4 affects the glass substrate through the ACF 5, and as shown in FIG. 15, the display area is even affected by the warping so as to cause a distorted deformation. As a result, the thickness of the liquid crystal layer changes locally by this distorted deformation, and the display unevenness (150) occurs at the display area nearby the IC chip mounting area owing to double refraction occurred in the glass substrate, and thereby aggravating the display quality. In particular, when a plurality of IC chips 4 are arranged along a straight line, the glass substrate transforms wavily. At that time, the wider the interval between adjacent IC chips 4, the larger the amplitude of the distorted deformation, and thus the shade of the display unevenness becomes worse. The longer the lengthwise direction of each of the IC chips 4, the larger the cycle of the distorted deformation, and thus the range of the display unevenness expands further.

In this way, in the process for mounting the IC chip 4 by means of a thermocompression together with the ACF, the distorted deformation of the glass substrate occurs inevitably. Because the display unevenness occurs as the result, improving means for such display unevenness is desired.

As an example of solving such problem, the above-mentioned patent document 1 proposes such technology that a slit is provided on the surface opposite to an active face of the mounted IC chip so as to absorb the shrinkage stress of the IC chip. According to the patent document 1, because the concave deformation with the shrinkage stress of the IC chip is absorbed by the slit portion, curvature deformation of the entire display panel could be prevented, and it is supposed that image quality deterioration would be prevented.

However, when the IC chip is heated and pressurized by the compression bonding tool from the face opposite to the active face of the IC chip in the compressing step of the IC chip, because the slit is provided on the interface with the compression bonding tool in the patent document 1, the projected electrode member arranged on the active face opposing to the slit portion does not receive the pressure, and thereby tending to cause such problem as connection fault.

As an another example of solving the above-mentioned problem, applicant of the present invention has proposed a display device in the above-mentioned patent document 2 as shown in FIG. 16 and FIG. 17 wherein two deformation suppression members 12 are provided between a display area and circuit components such as IC chips 4. By arranging the deformation suppression members 12 on a glass substrate, stiffness of the glass substrate is locally strengthened. Thus the warping in the IC chip mounted zone is suppressed so as not to affect the display area by suppressing transmission of deforming forth in the glass substrate.

Although the above-mentioned patent document 2 proposes that the distorted deformation of the glass substrate is compulsorily suppressed by arranging the deformation suppression members, there is room for improvement in the following points.

First, because the space is needed for providing the deformation suppression members, larger area is needed for mounting components, and results in disadvantageous for the miniaturization of the display device.

Second, because the deformation supression members and its bonding material are needed for the problem solution, number of parts are increased and increase in weight is inevitable for the display device where the weight saving is required.

### SUMMARY

An exemplary object of the present invention is to provide a display device and its manufacturing method which enables to suppress the occurrence of the display unevenness without increasing panel size and the number of parts by surely absorbing the stress due to the thermal deformation of the drive circuit component.

A display device according to an exemplary aspect of the present invention, stress absorption regions are formed within a glass substrate such that the stress absorption regions are arranged near or just below the mounted drive circuit components so as to absorb the stress caused by thermal deformation of the drive circuit components in such a display device provided with the drive circuit components on a glass substrate surface at peripheral portion outside a display area by using thermocompression bonding.

A method of manufacturing a display device according to an exemplary aspect of the present invention, a step of forming stress absorption region into the glass substrate so as to absorb the stress caused by thermocompression bonding of the circuit component.

### BRIEF DESCRIPTION OF THE DRAWINGS

Exemplary features and advantages of the present invention will become apparent from the following detailed description when taken with the accompanying drawings in which:

FIG. 1 is a plan view showing a structure of a display panel according to a first exemplary embodiment of the present invention.

FIG. 2 is a cross sectional view along the I-I line shown in FIG. 1.

FIG. 3A through FIG. 3D are schematic cross sectional views showing laser processing technology steps out of which a stress absorption region of the first exemplary embodiment of the present invention is formed.

FIG. 4 is a schematic perspective view of a part of the display panel according to the first exemplary embodiment of the present invention.

FIG. 5 is a plan view showing the other structure of the display panel according to the first exemplary embodiment of the present invention.

FIG. 6A is a plan view showing a structure of a display panel according to a second exemplary embodiment of the present invention.

FIG. 6B is a partial expanded plan view of a dotted line section 61 in FIG. 6A.

FIG. 7A is a plan view showing the other structure of the display panel according to the second exemplary embodiment of the present invention.

FIG. 7B is a partial expanded plan view of a dotted line section 71 in FIG. 7A.

FIG. 8A Is a plan view showing the other structure of a display panel according to the second exemplary embodiment of the present invention.

FIG. 8B is a partial expanded plan view of a dotted line section 81 in FIG. 8A.

FIG. 9A is a plan view showing the other structure of the display panel according to the second exemplary embodiment of the present invention.

FIG. 9B is a cross sectional view along the II-II line shown in FIG. 9A.

FIG. 10 is a cross sectional view along the III-III line shown in FIG. 9A.

FIG. 11A through FIG. 11D are plan views showing the other structure of the display panel according to the second exemplary embodiment of the present invention.

FIG. 12 is a plan view showing a structure of a related art display panel.

FIG. 13 is a perspective view showing a compression bonding step for an IC chip.

FIG. 14 is a cross sectional view along the IV-IV line shown in FIG. 12.

FIG. 15 is a perspective view of the related art display panel.

FIG. 16 is the plan view showing the structure of the display panel in the patent document 2.

FIG. 17 is a cross sectional view along the V-V line shown in FIG. 16.

### EXEMPLARY EMBODIMENTS

Exemplary embodiments of the present invention will now be described in detail in accordance with the accompanying drawings.

### Exemplary Embodiment 1

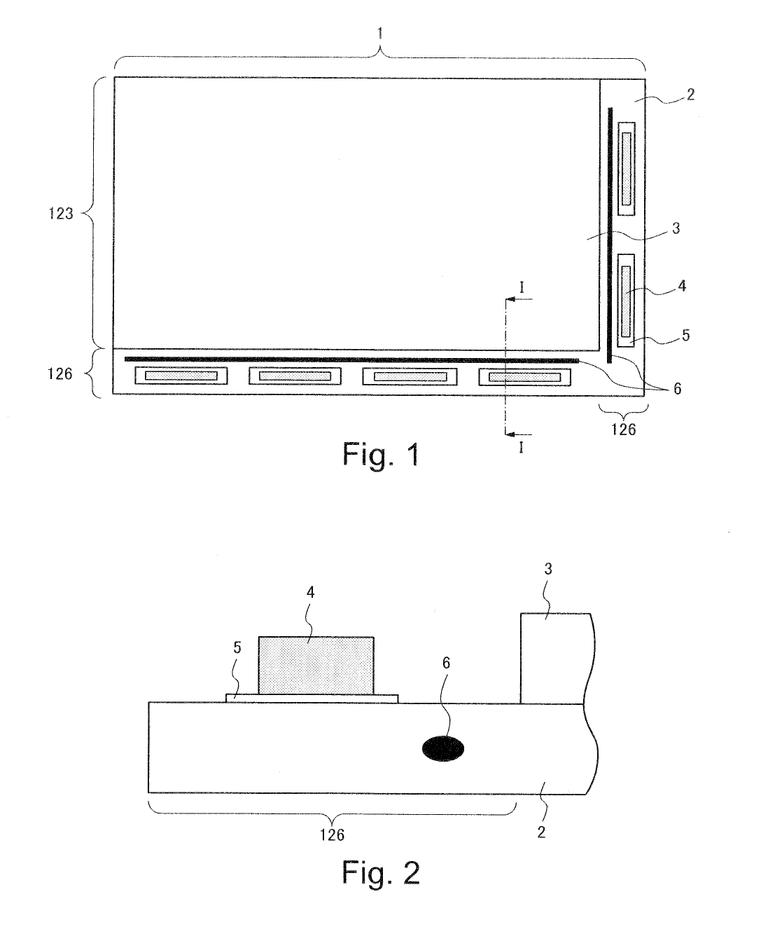

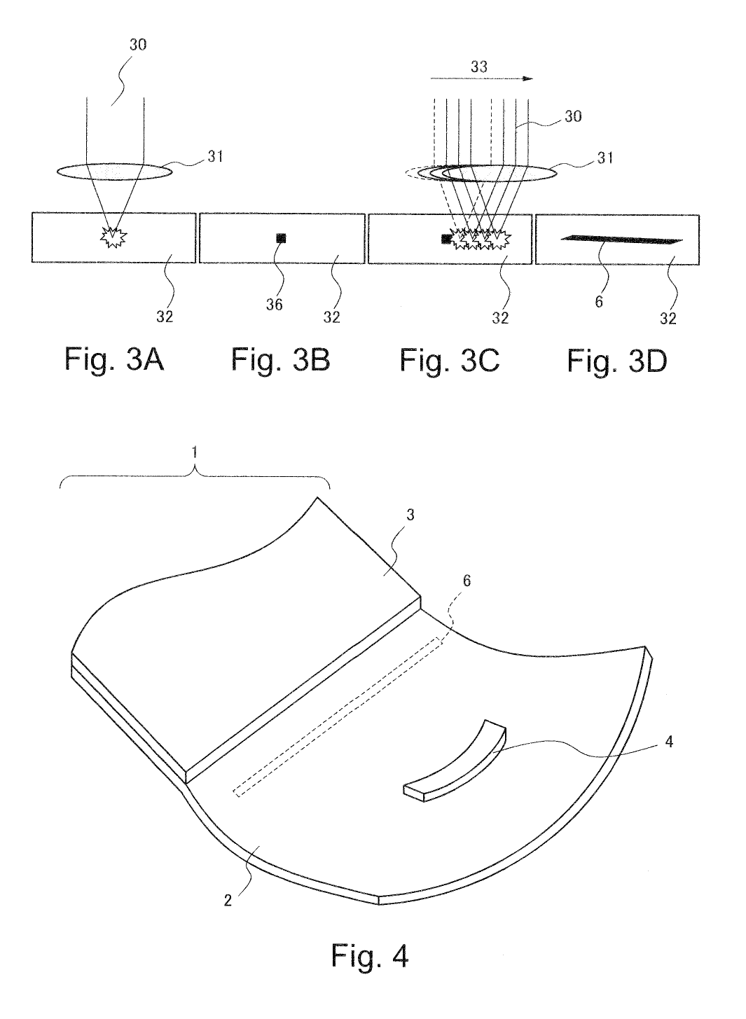

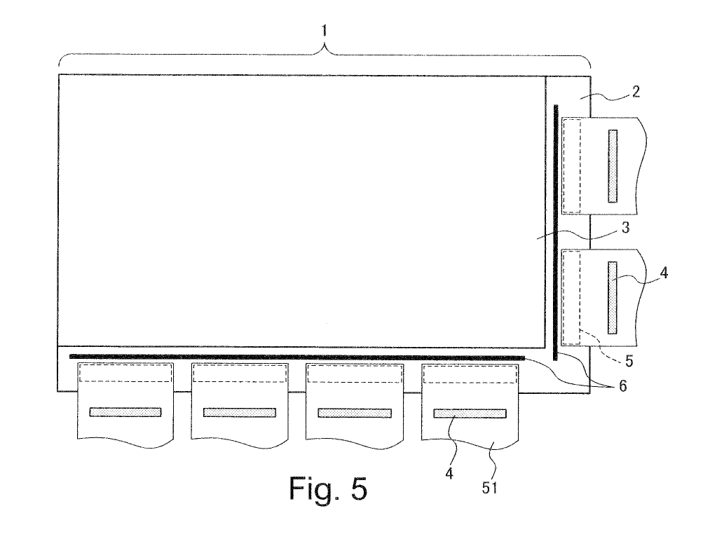

First, a display device according to the first exemplary embodiment of the present invention will be described with reference to FIG. 1 through FIG. 5. FIG. 1 is a plan view showing a structure of a display panel according to the first exemplary embodiment of the present invention, and FIG. 2 is a cross sectional view along the I-I line shown in FIG. 1. FIG. 3A through FIG. 3D are cross sections showing forming processes of the stress absorption regions of this exemplary embodiment, and FIG. 4 is a perspective view showing the state after mounting an IC chip on the display panel of this exemplary embodiment. FIG. 5 is a plan view showing the other structure of the display panel according to this exemplary embodiment.

As shown in FIG. 1, a display panel 1 of this exemplary embodiment includes two glass substrates each having thickness in the order of 0.7 mm, one of which is a thin film transistor substrate (hereinafter, abbreviated as a TFT substrate 2) provided with transistors, signal lines and scanning lines, and pixel electrodes (not shown), and being bonded with an opposed substrate 3 so as to be sandwiched between a pair Of polarizers (not shown) Although the opposed substrate 3 may be a so-called CF (Color Filter) substrate provided with transparent common electrode and color layers associated with each pixel, for example it may be a monochrome filter substrate not having the color layers, and moreover, it may be a filter substrate not having the transparent common electrode. A liquid crystal layer (not shown) is interposed between the TFT substrate 2 and the CF substrate 3.

The overall size of the TFT substrate 2 is made larger than that of the CF substrate 3 such that terminal electrodes extended from the signal lines and the scanning lines are formed on exposed peripheral area 126 of the TFT substrate 2 which is not opposing to the CF substrate 3 and thereby providing such structure that the terminal electrodes are connected to projected electrodes of the IC chips 4 serving as drive circuit components.

Each of the IC chips 4 has an approximate shape of rectangular parallelepiped with thickness in the order of 0.2 mm to 0.6 mm, and being connected to the terminal electrodes via the ACF 5 by using the thermocompression bonding. The IC chips 4 provide output signals to the display panel 1 so as to control the display panel 1 by inputting electric signals to the IC chips 4 from the printed wiring board which is not illustrated.

AS for the formation of the stress absorption regions 6 that is significant feature of this exemplary embodiment, such a laser marking technology as a sub-surface marking or an inner glass marking (IGM) is available. The stress absorption regions 6 are designed such that countless micro cracks are generated by inducing thermal strain within the TFT substrate 2 by generating such optical damages called “Optical Damage” or “Optical Breakdown” caused by the nonlinear absorption by concentrating a high output laser beam within the glass substrate. In a plane view, these stress absorption regions 6 are located between the IC chip mounted area and the display area 123, and each of them is extended along the long side direction of the IC chips 4 so as to extend like a straight line having a width of about 0.1 mm to 0.2 mm and longer than a distance between ends of outermost IC chips along each side edges of the TFT substrate 2.

As shown in FIG. 2 which is the cross sectional view along the I-I line shown in FIG. 1, each of the stress absorption region 6 is formed at an approximately middle portion in a thickness wise direction of the TFT substrate 2 with a height in the order of 0.1 mm to 0.2 mm.

In the method of manufacturing the liquid crystal display device according to this exemplary embodiment, the stress absorption regions 6 are previously formed at a stage of a raw glass plate prior to forming the TFT substrate 2.

Hereinafter, the method of manufacturing the liquid crystal display device of this exemplary embodiment is described referring a formation principle of the stress absorption regions 6.

First, as shown in FIG. 3A, a laser beam 30 is focused at middle area of a glass substrate 32 by using a lens 31. As an example of the laser beam 30 having an unabsorbed wavelength in the glass, a nano-second laser such as Nd-YAG (Neodymium-Yttrium Aluminum Garnet) laser and Nd-YLF (Neodymium-Yttrium Lithium Fluoride) laser is used. The laser beam 30 is concentrated such that its energy density will be no smaller than a threshold value that causes nonlinear absorption inside the glass substrate 32. When the nonlinear absorption is caused inside the glass substrate, the absorbed energy is turned into heat, and the glass substrate is locally heated. Thus the heated hot glass or partially gasificated glass provides volume expansion to induce optical characteristic change in refractive index and absorbance, and further causes stress distortion inside the glass substrate. Countless micro cracks 36 are produced by the process that eases this stress (FIG. 3B referred to). Size and direction of the micro cracks can be controlled by the irradiation energy of the laser beam and the degree of incident angle, and a center portion of the cracks will be in a hollow state. The micro cracks can be brought about in an optional position by moving a concentrating point which causes such micro cracks as shown in the arrow 33 shown in FIG. 3C. As a result, as shown in FIG. 3D, the stress absorption region 6 having aggregation of the micro cracks and a hollow portion is formed inside the glass substrate 32.

The display panel 1 will be completed by applying publicly known TFT manufacturing technology and panel manufacturing technology to the glass substrate provided with the stress absorption regions 6 in the area to be mounted with the IC chips 4 by the laser irradiation based on the above-mentioned principle.

After the ACF 5 is printed on the terminal electrode area of the display panel 1, the IC chips 4 are arranged on the ACF 5 and then subjected to thermocompression bonding with predetermined temperature, pressure and time to fix the IC chips 4 on the display panel 1 by hardening the ACF 5. As a result, the projected electrodes of the IC chips 4 and the terminal electrodes of the display panel 1 are electrically connected via the conductive particles in the ACF 5.

And then, a flexible board or printed wiring board will be connected to the produced display panel 1, and a backlight unit and a case are assembled to complete a liquid crystal display device.

In the foregoing description, the stress absorption regions 6 are formed into the glass substrate prior to the display panel production. This is because, when the thin film pattern such as the TFT wiring exists in the laser irradiation area for forming the stress absorption regions 6, the thin film pattern tends to receive the damage if the laser output energy level is high. Although the wiring pattern connected to the TFT device in the display area generally exists around the IC chip mounted area, when the formed pattern of the wiring pattern layout and the stress absorption region 6 are arranged suitably so as not be irradiated by the laser beam, the stress absorption regions 6 can be formed either after the wiring patterning process or after the IC chip mounting process without causing any problem.

The display panel 1 produced by the above-mentioned method provides locally improved flexibility because the thickness of the glass substrate becomes thin at the stress absorption regions 6 having the hollow parts inside the glass substrate. Therefore, as shown in FIG. 4, even if the glass substrate deformation occurs due to occurring the shrinkage stress at the IC chips 4 by the thermocompression bonding using the ACF 5, the stress (the deformation distortion) is absorbed by the stress absorption regions 6, and thus the affection of the glass substrate deformation to the display area is suppressed.

Accordingly, the deformation distortion of the glass substrate in the display area is reduced and the local gap change in the liquid crystal layer and the double refraction of the glass substrate can be suppressed, and the occurrence of the display unevenness can be reduced, and thus the high-quality liquid crystal display device can be provided.

Furthermore, because the stress absorption regions 6 are formed inside the glass substrate, there are no cases that the miniaturization of the display device is disturbed. In addition, because the extra components are not used, the high-quality liquid crystal display device can be provided without increasing the number of components.

In this exemplary embodiment, although the stress absorption regions 6 are formed by locally destructing the inside of the glass substrate, there is no problem in terms of actual use in its strength so long as the stress absorption regions 6 are located at the approximately central portion of the glass substrate in the thickness wise direction with such a size (the height) that the distance to the front and rear surfaces of the glass substrate from it is sufficient such that the micro cracks of the stress absorption regions 6 do not progress to the extent of the front and rear surfaces of glass substrate (for example, in the order of at most 30% of the thickness of the glass substrate).

In this exemplary embodiment, although it has been described based on the case of the COG mounting which mounts the IC chips 4 on the glass substrate directly, the present invention can be applied to other mounting systems such as the COF mounting and the TCP mounting which mount the IC chips 4 on the flexible substrate 51 as shown in FIG. 5, the deformation of the glass substrate can be suppressed by forming the stress absorption regions 6 in the same manner.

### Exemplary Embodiment 2

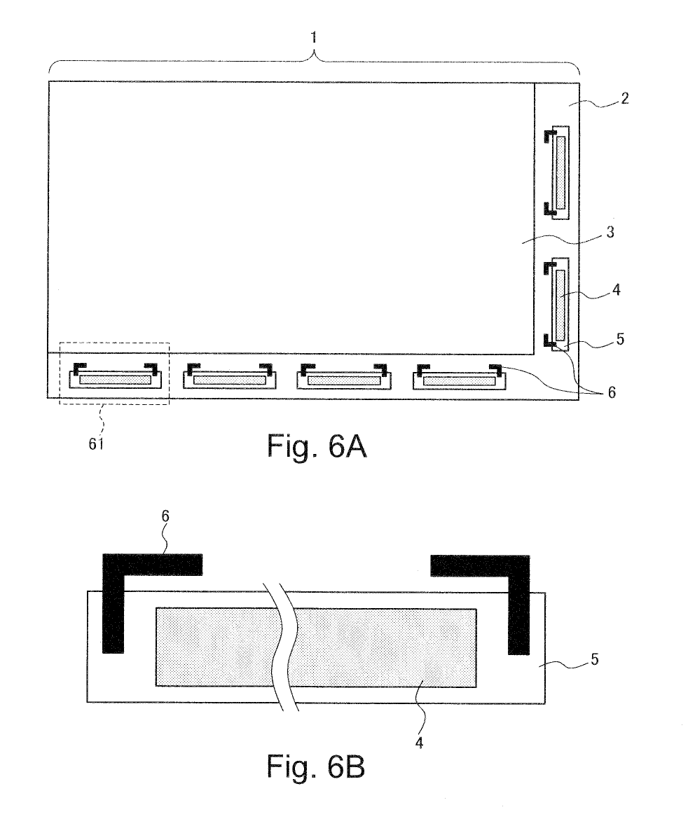

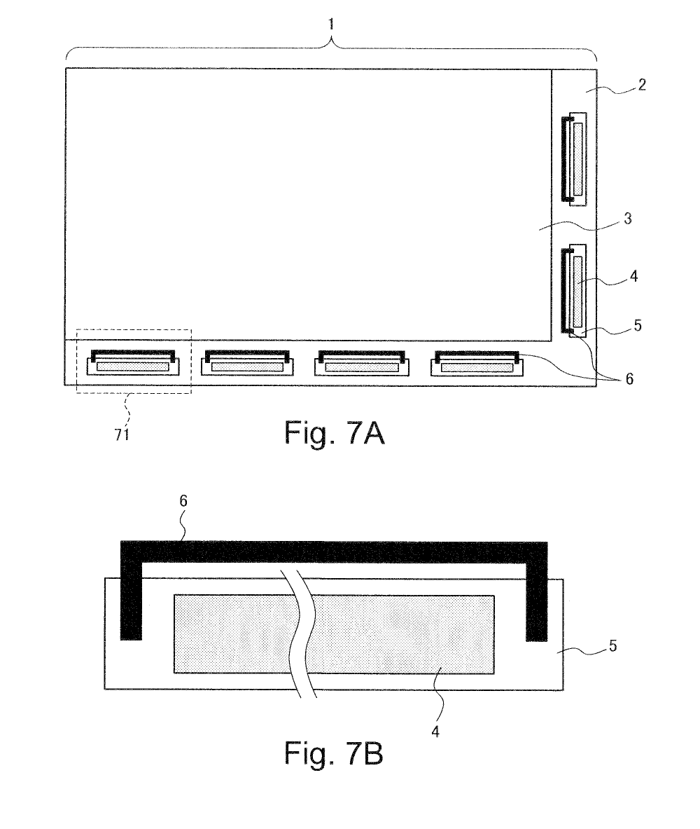

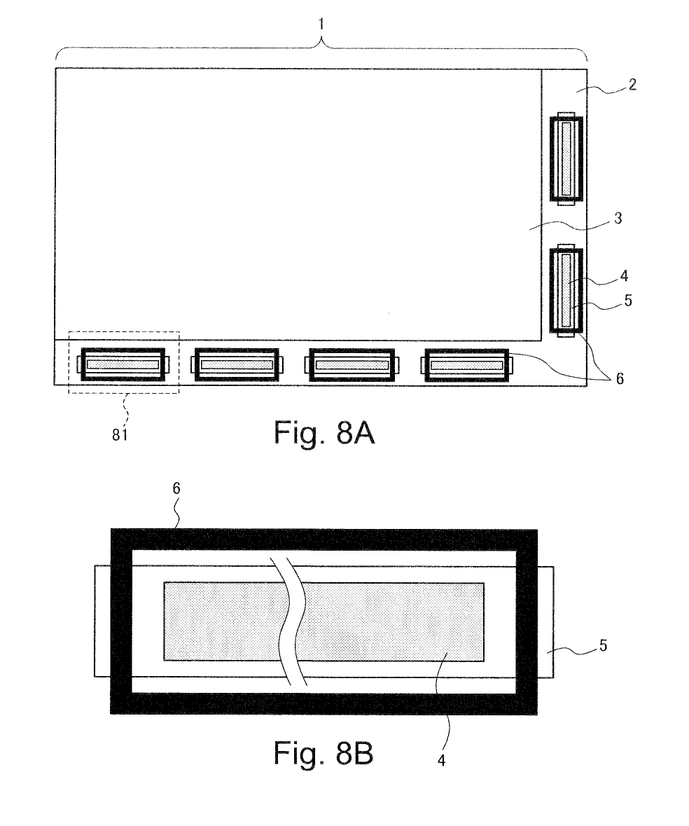

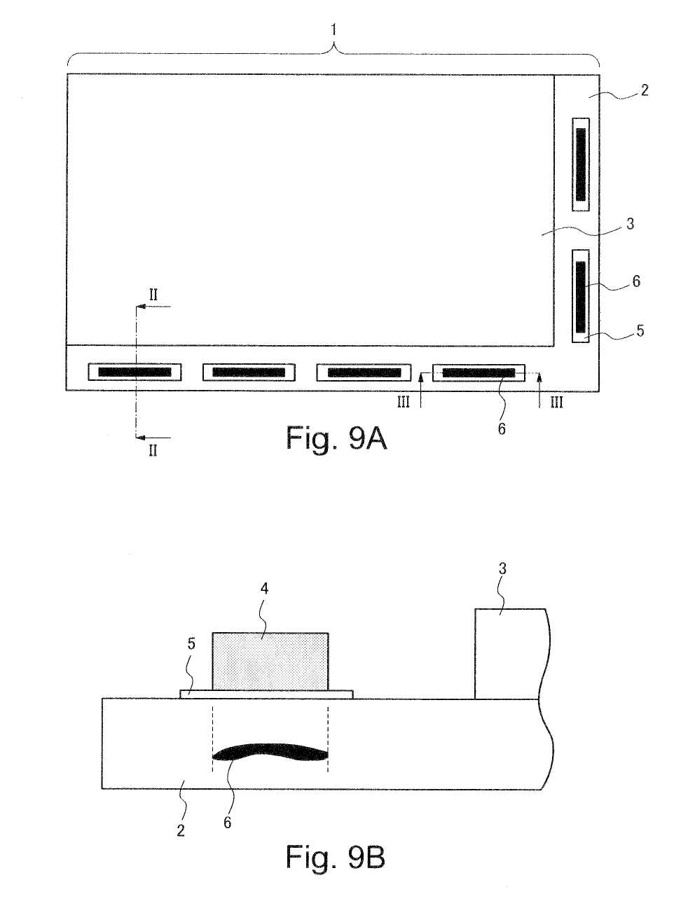

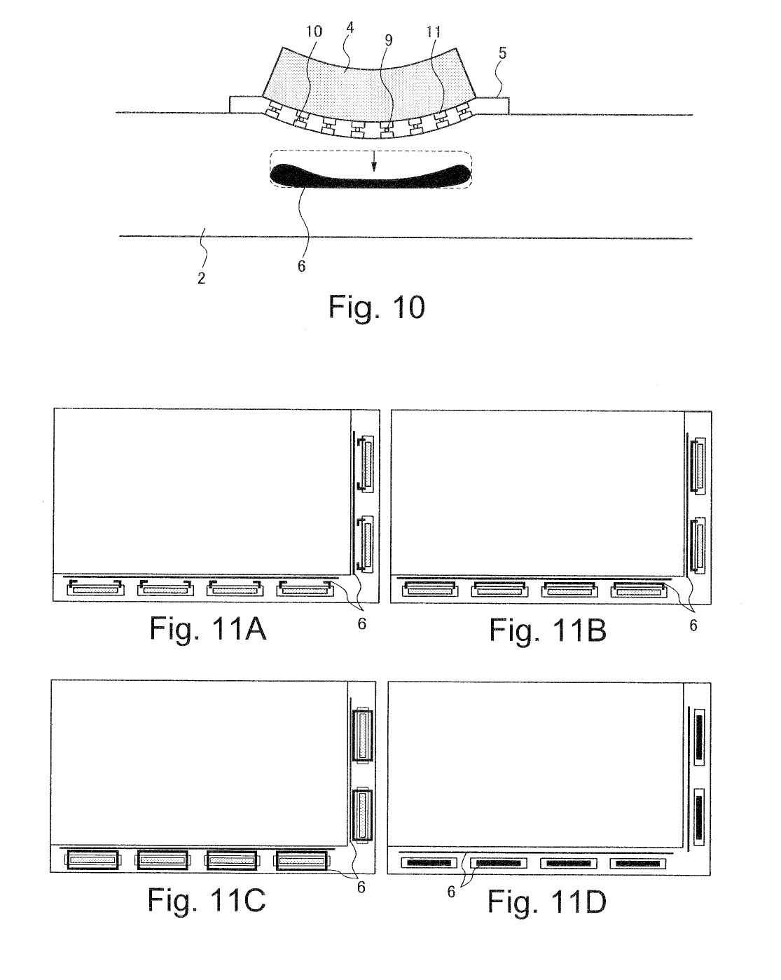

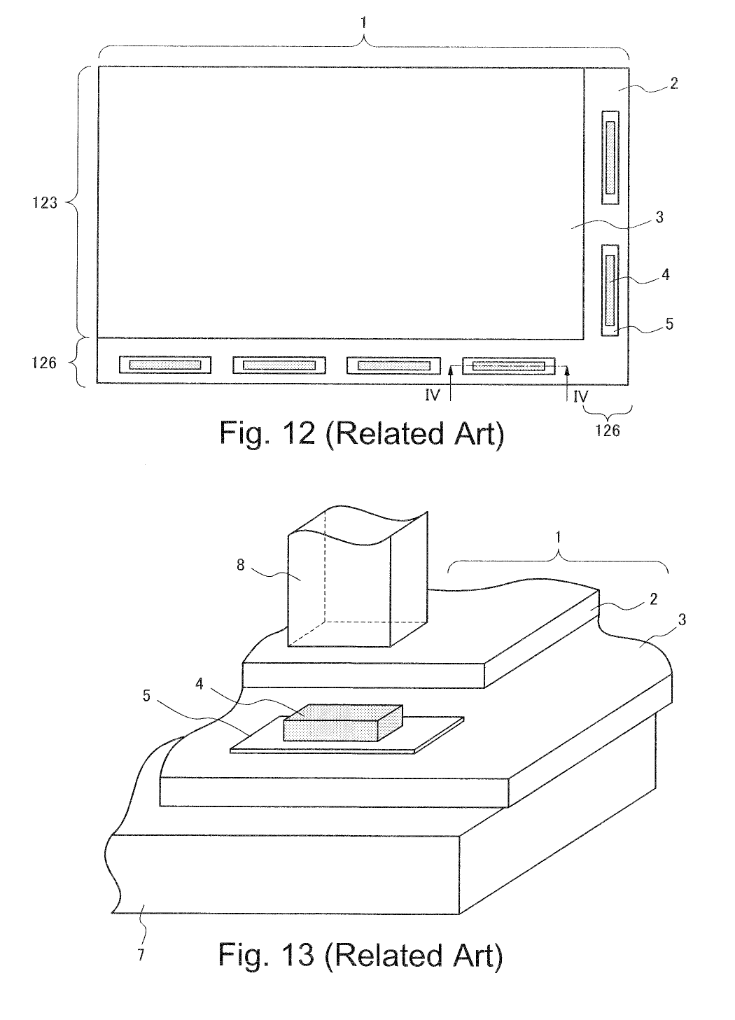

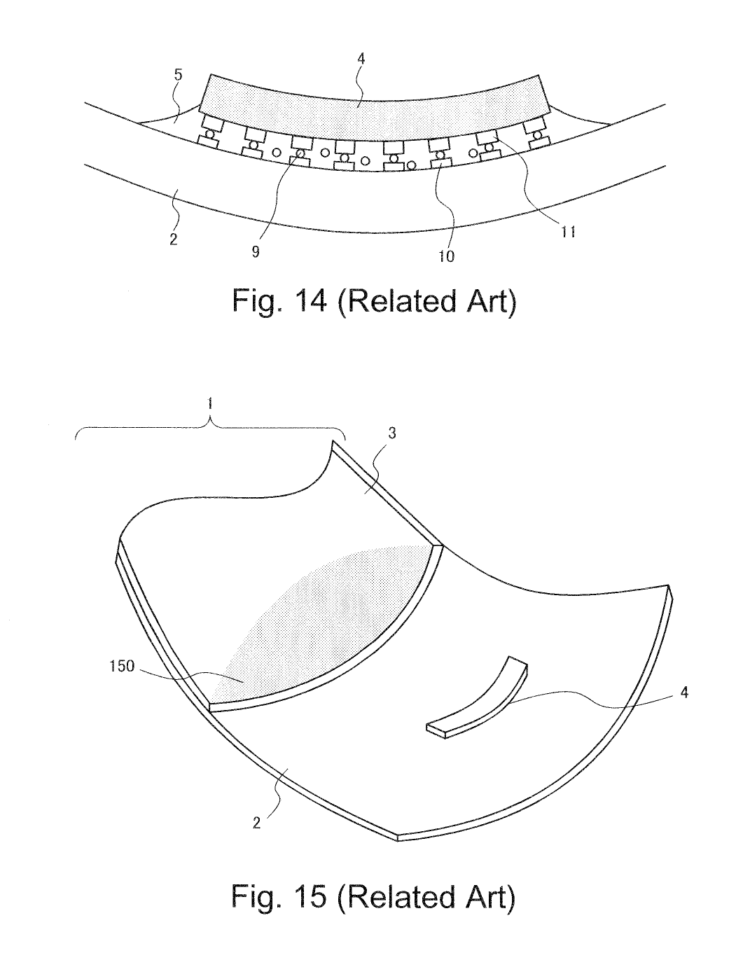

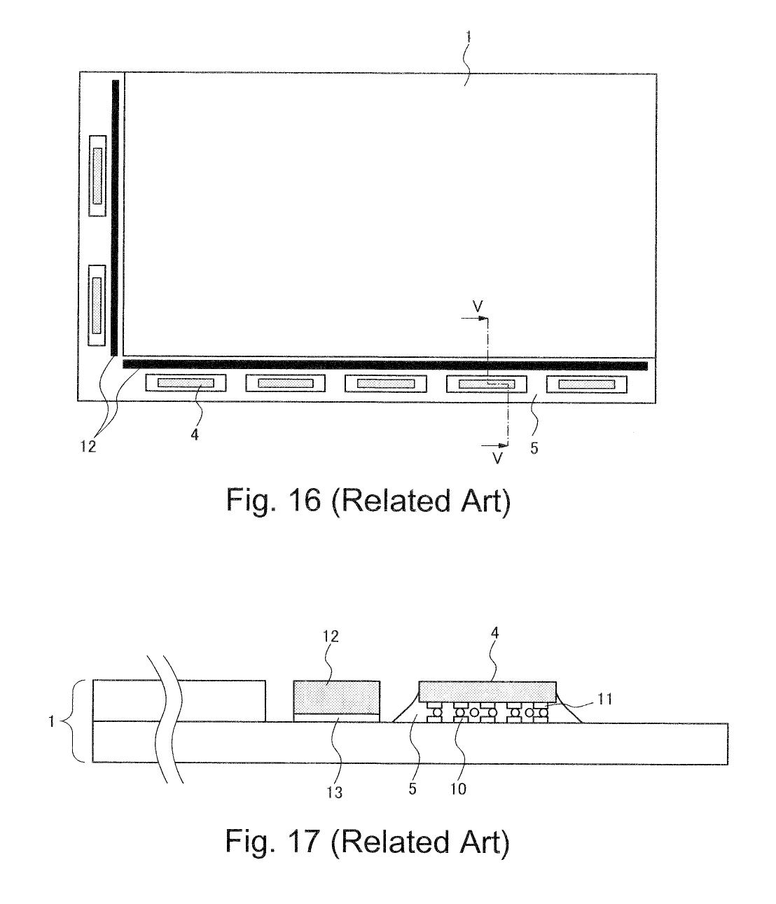

Next, a display device according to a second exemplary embodiment of the present invention will be described with reference to FIG. 6 through FIG. 11. Among those figures, FIG. 6A, FIG. 7A and FIG. 8A are plan views showing the structures of the display panel related to the second exemplary embodiment of the present invention, and FIG. 6B, FIG. 7B and FIG. 8B are partial expanded plan views corresponding to respective dotted line section in FIG. 6A, FIG. 7A and FIG. 8A. FIG. 9A is a plan view showing the other structure of the display panel according to the second exemplary embodiment and FIG. 9B is a cross sectional view along the II-II line shown in FIG. 9A. FIG. 10 is a cross sectional view along the III-III line of FIG. 9A. FIGS. 11A to 11D are plan views showing additional other structures of the display panels according to this exemplary embodiment. This exemplary embodiment is achieved by revising the shape of the stress absorption regions of the first exemplary embodiment mentioned above.

In the first exemplary embodiment mentioned above, although each of the stress absorption regions 6 is formed like the straight line, other shape is also available so long as it enable to absorb the stress of the glass substrate, for example, as shown in FIG. 6A and FIG. 6B, each of the stress absorption regions 6 may be formed to have a shape of capital letter “L” along at least two corners of each of the IC chips 4 such that a part of each stress absorption region 6 is located between the display area and the two corners which are located closer to the display area. In this configuration, because the stress absorption regions 6 enable to absorb the deformation of the glass substrate caused by large stress in particular around the corners of the IC chip 4, it is possible to suppress the affection of the glass substrate deformation toward the display area direction, and thereby reducing the occurrence of the display unevenness.

Furthermore, as shown in FIG. 7A and FIG. 7B, each of the stress absorption regions 6 can be formed in such a shape of a shallow-bottomed capital letter “U” such that the bottom portion of which is located between the display area and a long side of each IC chip 4 closer to the display area and two wall portions of which is extended along two short sides of each IC chip 4 at least. Moreover, as shown in FIG. 8A and FIG. 8B, each of the stress absorption regions 6 can be formed to have a frame-like shape so as to surround four sides of each IC chip 4 In these configurations shown in FIG. 7 and FIG. 8, since the stress absorption regions 6 are formed so as to surround at least three sides of the IC chip 4 serving as a source for generating the glass substrate deformation toward the display area can be suppressed more effectively, and thus the occurrence of the display unevenness can be reduced.

In addition, as shown in FIG. 9A and FIG. 9B, each stress absorption region 6 may be formed to have an approximately same shape of each of the mounted IC chips 4 so that the stress absorption regions 6 are located just beneath the IC chip mounting area. In this configuration, as shown in FIG. 10, because the glass substrate just beneath the IC chip mounting areas becomes thin owing to the stress absorption regions 6, the glass substrate deformation due to the shrinkage stress of the IC chip 4 can be absorbed by deforming the stress absorption regions 6 themselves, and thereby almost preventing the affection of the deformation of the glass substrate toward the surrounding portion of the IC chips 4. A group of electrodes 11 of the IC chip 4 and a group of terminal electrodes 10 of the TFT substrate 2 are electrically connected via conductive particles 9 of the ACF 5.

Moreover, as shown in FIGS. 11A to 11D, each of the stress absorption regions 6 can be made to have such a shape that the straight line-like stress absorption region 6 indicated in the first exemplary embodiment mentioned above is combined with those shown in FIG. 6 through FIG. 9, so as to further reduce the affection of the glass substrate deformation towards the display area and thereby providing such a high-quality liquid crystal display device that reduces the display unevenness.

That is, the shape of the stress absorption regions 6 shown in FIG. 11A is a configuration obtained by adding the stress absorption region 6 shown in FIG. 1 to the display device shown in FIG. 6. Similarly, the shape of the stress absorption regions 6 shown in FIG. 11B is a configuration obtained by adding the stress absorption region 6 shown in FIG. 1 to the display device shown in FIG. 7. The shape of the stress absorption regions 6 shown in FIG. 11C is a configuration obtained by adding the stress absorption region 6 shown in FIG. 1 to the display device shown in FIG. 8, and the shape of the stress absorption regions 6 shown in FIG. 11D is a configuration obtained by adding the stress absorption region 6 of FIG. 1 to the display device shown in FIG. 9.

The stress absorption regions 6 do not need to be separated each other along each side direction of each IC chip 4 or the display area, and it is also not necessary to be continuous like the straight line, and it would be formed like a dotted line or a curved shape. So long as the stress absorption regions are located at least either between the display area and the IC chip mounting area or just beneath of the IC chip mounting area, any shape of the stress absorption regions is available.

In each above-mentioned exemplary embodiment, although the mounted structure of the present invention is applied to the display panel for the liquid crystal display device, the present invention is not limited to the above-mentioned exemplary embodiments, but it can also be applied to an arbitrary display device provided with a component serving as a stress source on the glass substrate.

The present invention is available to any display device in general such as the liquid crystal display device.

The patent document 1 as a related art described in the background art causes a problem, such as low connection reliability for the opposing part to the slit provided on the IC chip. Although there is also a method to arrange the deformation suppression member in the gap of the circuit component and the display area shown in the patent document 2, it becomes disadvantageous to the miniaturization and the weight saving of the display device by this method.

An exemplary advantage according to the invention is that it is possible to reliably absorb the stress caused by the thermal deformation of the drive circuit component, and suppress the occurrence of the display unevenness without increasing the size and the number of components.

In the above mentioned exemplary embodiments, although the liquid crystal display device has been described as the display device, the present invention is not limited to this, and they may be a plasma display and an organic EL (Electroluminescence) display or the like. Moreover, mounting system is not limited to the COG mounting but the TCP mounting and the COF mounting can be used. Further, the adhesion material is not limited to film-shaped ACF, but it is applicable widely in the mounting method using the adhesion material resin of the thermal hardening type or the thermoplastic type such as the paste-like ACP (Anisotoropic Conductive Paste), NCF (Non Conductive Film) not including the conductive particles and NCP (Non Conductive Paste). That is, the present invention can be applied to arbitrary display devices having such mounted structures that the thermal expansion difference between the glass substrate and the circuit component for drive by the thermocompression bonding bring about the deformation of the glass substrate and the gap change to affect display quality.

In the present invention, each of the stress absorption regions can be formed to have following various structures. It is formed along the display area side of the drive circuit component between the display area and the mounting area of the drive circuit component. It is formed to have a shape of capital letter “L” along each corner of the drive circuit component at a side of the display area. It is formed to have a shape of capital letter “U” along three side edges of the drive circuit component at a side of the display area. It is formed to have a frame shape along the entire circumference of the drive circuit component. It is formed to approximately overlap with the drive circuit component when it is viewed from the normal direction of the glass substrate.

In the present invention, it is desirable that the stress absorption region includes the hollow part and the aggregation of micro cracks.

According to the present invention, since the stress absorption regions are formed inside the glass substrate, new additional elements are not necessary, and the extra spaces for arranging the deformation suppression members also becomes unnecessary. In addition, there is no occurrence of the raising dust owing to forming the stress absorption regions. Furthermore, because each of the stress absorption regions has the hollow part, the flexibility of the glass substrate is locally increased. Accordingly, even if the glass substrate deformation occurs around the IC chips owing to the shrinkage stress of the IC chip, the stress (the deformation distortion) is absorbed by the stress absorption region, and thus the deformation distortion in the display area of the glass substrate can be eased and provide the high-quality display device without the display unevenness as the result. Since the stress absorption regions are provided inside the glass substrate, the pressure disproportion when pressurizing process using the compression bonding tool does not occur, and thereby preventing the occurrence of the connection fault.

According to the display device of the present invention, by providing the stress absorption regions nearby the IC chip mounting areas, it enables to suppress the affection of the stress (the deformation distortion) on the glass substrate mount ed with the IC chip toward the display area, and thus the local gap change in the liquid crystal layer and the double refraction of the glass substrate can be reduced, and thereby suppressing the occurrence of the display unevenness of the display device.

Furthermore, since the stress absorption regions are formed by using hollow processing inside the glass substrate, the flexibility can be improved locally without changing the flatness of the glass surface of substrate. Since there is no dust raising process for forming the stress absorption region inside the glass substrate, there is no need to set up a special washing step or the like, and thus enabling to produce the display device by the usual manufacturing steps.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

Further, it is the inventor's intention to retain all equivalents of the claimed invention even if the claims are amended during prosecution.

What is claimed is:

1. A display device, comprising:
a glass substrate having a display area and a peripheral area;
a drive circuit component mounted on said glass substrate by thermocompression bonding on said peripheral area; and
a stress absorption region provided within said glass substrate close to said circuit component so as to absorb stress produced by thermal deformation of said circuit component.

2. The display device according to claim 1, wherein said stress absorption region is located between said display area and said circuit component so as to extend along a side portion of said circuit component adjacent to said display area.

3. The display device according to claim 1, wherein said stress absorption region is located around two corners of said circuit component disposed nearby said display area so as to extend along each of said two corners in a shape of capital letter “L”.

4. The display device according to claim 1, wherein said stress absorption region is located around three sides of said circuit component disposed nearby said display area so as to extend along said three sides in a shape of capital letter “U”.

5. The display device according to claim 1, wherein said stress absorption region is located so as to surround said circuit component in a frame shape.

6. The display device according to claim 1, wherein said stress absorption region is located so as to be overlapped with said circuit component in a normal direction of said glass substrate.

7. The display device according to claim 1, wherein said stress absorption region includes a hollow part and aggregation of micro cracks.

8. A method of manufacturing a display device comprising:
forming stress absorption region inside a glass substrate located between a display area and a group of terminal electrodes; and
fixing a circuit component on said group of terminal electrodes by using thermocompression bonding.

9. The method of manufacturing the display device according to claim 8, wherein said stress absorption region is formed by irradiating a laser beam into said glass substrate so as to form a hollow part and aggregation of micro cracks.

10. The method of manufacturing the display device according to claim 9, wherein said stress absorption region is formed at central portion of said glass substrate in a thickness direction thereof.
